(19) United States
(12) Patent Application Publication
(10) Pub. No.: US 2026/0299016 A1
(43) Pub. Date: Oct. 1, 2026

(54) DETECTING DISTRIBUTED VOLTAGE REGULATOR FAILURES

(71) Applicant: INTERNATIONAL BUSINESS MACHINES CORPORATION, ARMONK, NY (US)

(72) Inventors: MICHAEL SPERLING, POUGHKEEPSIE, NY (US); JENS DACI, POUGHKEEPSIE, NY (US)

(21) Appl. No.: 19/095,647

(22) Filed: Mar. 31, 2025

(51) Int. Cl. G01R 31/28; G05F 1/56

(52) U.S. Cl. CPC G01R 31/2884; G05F 1/56

(57) ABSTRACT

Detecting distributed voltage regulator failures including providing an integrated circuit having a plurality of voltage regulators in a voltage domain, a voltage detector, and a voltage comparator; enabling only a first voltage regulator from the plurality of voltage regulators; with only the first voltage regulator enabled, measuring an output voltage from the voltage domain by the voltage detector; and determining the first voltage regulator has failed by the voltage comparator finding that a difference between the output voltage and an expected voltage from the voltage domain is greater than a threshold.

### BACKGROUND

The present disclosure relates to methods, apparatus, and products for detecting distributed voltage regulator failures.

### SUMMARY

According to embodiments of the present disclosure, various methods, apparatus and products for detecting distributed voltage regulator failures are described herein. In some aspects, detecting distributed voltage regulator failures includes providing an integrated circuit having a plurality of voltage regulators in a voltage domain, a voltage detector, and a voltage comparator; enabling only a first voltage regulator from the plurality of voltage regulators; with only the first voltage regulator enabled, measuring an output voltage from the voltage domain by the voltage detector; and determining the first voltage regulator has failed by the voltage comparator finding that a difference between the output voltage and an expected voltage from the voltage domain is greater than a threshold.

### BRIEF DESCRIPTION OF THE DRAWINGS

FIG. 1 sets forth an example computing environment according to aspects of the present disclosure.

FIG. 2 sets forth an example system for detection of distributed voltage regulator failures according to aspects of the present disclosure.

FIG. 3 sets forth a flowchart of an example method for detecting distributed voltage regulator failures according to aspects of the present disclosure.

### DETAILED DESCRIPTION

Voltage domains within integrated circuits include multiple voltage regulators to maintain an output voltage across the loads within the domain. Aspects of the present disclosure may be used to isolate failures within the group of voltage regulators to determine which voltage regulator or regulators are the source of failure that cause incorrect voltage output.

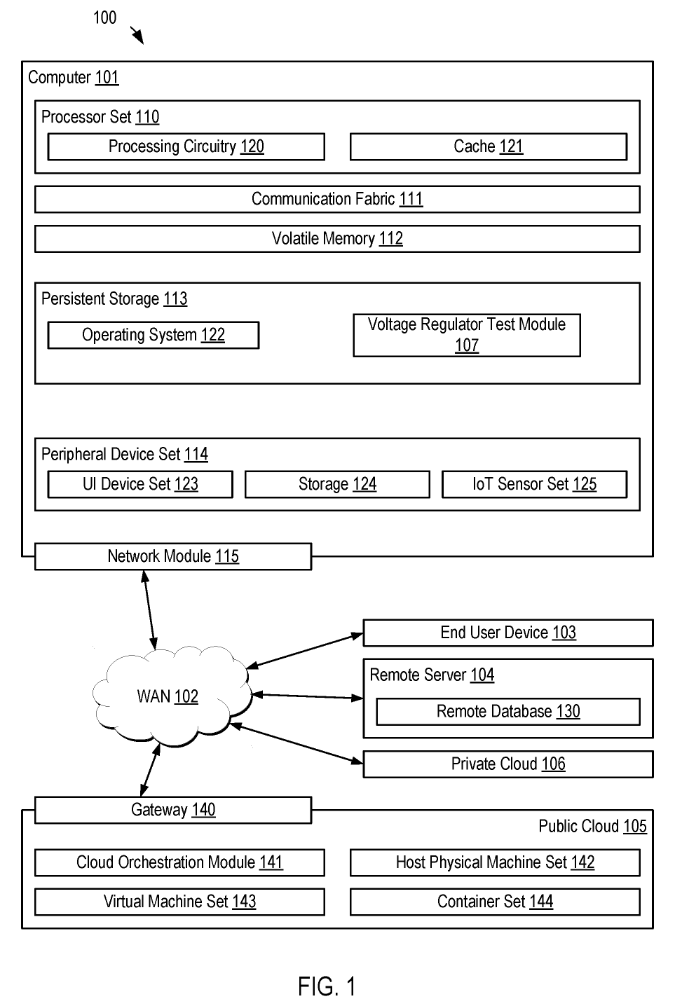

FIG. 1 sets forth an example computing environment according to aspects of the present disclosure. Computing environment 100 contains an example of an environment for the execution of at least some of the computer code involved in performing the various methods described herein, such as voltage regulator test module 107. In addition to voltage regulator test module 107, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and voltage regulator test module 107, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 121 and the other storage media discussed below. The program instructions, and associated data, are accessed by processor set 110 to control and direct performance of the computer-implemented methods. In computing environment 100, at least some of the instructions for performing the computer-implemented methods may be stored in voltage regulator test module 107 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input / output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in voltage regulator test module 107 typically includes at least some of the computer code involved in performing the computer-implemented methods described herein.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database), this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the computer-implemented methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider’s systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

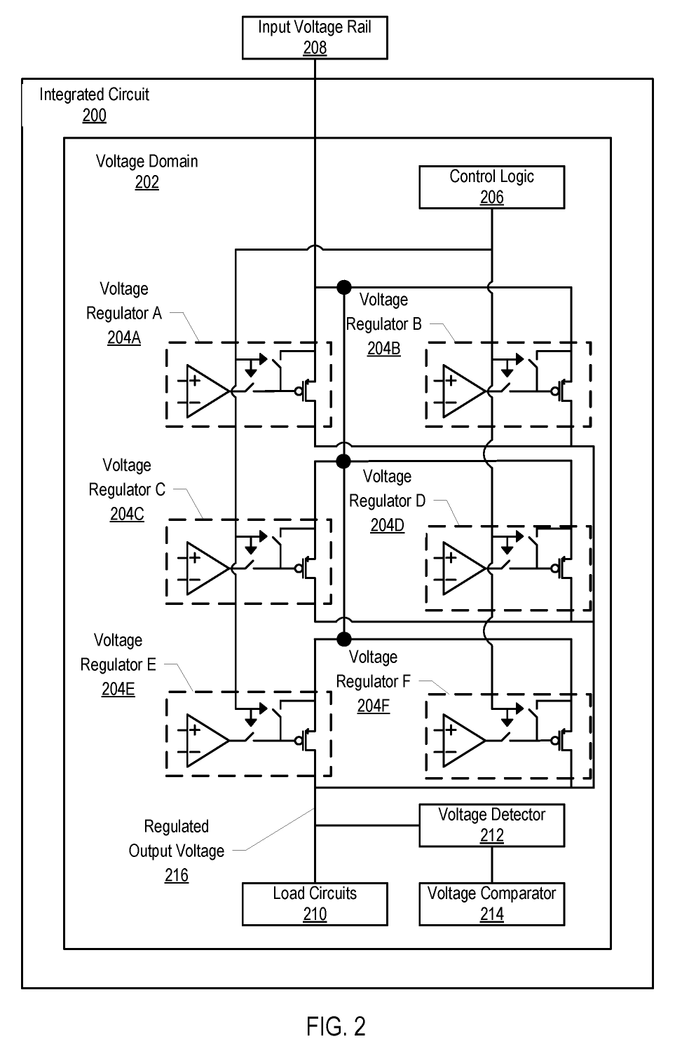

FIG. 2 sets forth an example system for detection of distributed voltage regulator failures according to aspects of the present disclosure. As shown in FIG. 2, the example system includes an input voltage rail 208 and an integrated circuit 200 that includes the voltage domain 202. The voltage domain 202 includes multiple voltage regulators (voltage regulator A 204A, voltage regulator B 204B, voltage regulator C 204C, voltage regulator D 204D, voltage regulator E 204E, voltage regulator F 204F), control logic 206, and a load circuits 210 powered via the voltage regulators. The integrated circuit 200 also includes a voltage detector 212 and a voltage comparator 214. The output of the voltage regulators is the regulated output voltage 216.

The input voltage rail 208 is the source of power for the integrated circuit 200. The integrated circuit 200 is a collection of electronic components and interconnections etched into a semiconductor material. The integrated circuit 200 may include, for example, a processing unit, data storage, power management, or input and output functions. The integrated circuit 200 may include one or more voltage domains. A voltage domain 202 is a group of electronic components that share a voltage supply.

Each voltage regulator (voltage regulator A 204A, voltage regulator B 204B, voltage regulator C 204C, voltage regulator D 204D, voltage regulator E 204E, voltage regulator F 204F) is a circuit that is designed to maintain a constant output voltage level as operating conditions change over time. That is, the voltage regulator receives an input voltage and automatically maintains a constant voltage level on one or more output terminals. There are several types of voltage regulators such as, for example, switching regulators, linear regulators, and cascaded regulators that may include both switching and linear regulators in a cascaded architecture. One particular type of linear regulator that may be used is a low-dropout (LDO) regulator. An LDO regulator is a linear voltage regulator that may regulate the output voltage even when the supply voltage is close to the output voltage. That is, the LDO regulator may maintain voltage regulation with small differences between supply voltage and load voltage. Another type of voltage regulator is a buck switching regulator (e.g., a step-down regulator circuit). The buck switching regulator is a type of switch mode power supply circuit designed to efficiently reduce voltage from a higher voltage to a lower voltage.

As shown in FIG. 2, each voltage regulator (voltage regulator A 204A, voltage regulator B 204B, voltage regulator C 204C, voltage regulator D 204D, voltage regulator E 204E, voltage regulator F 204F) include an amplifier and a transistor. The amplifier acts as a control for the voltage across the gate of the transistor. The voltage regulators also include circuitry to enable or disable each voltage regulator. The voltage regulators may be distributed across the voltage domain 202 to regulate the voltage across different loads.

The control logic 206 is a collection of electronic components configured to enable or disable each of the voltage regulators (voltage regulator A 204A, voltage regulator B 204B, voltage regulator C 204C, voltage regulator D 204D, voltage regulator E 204E, voltage regulator F 204F) within the voltage domain 202. Specifically, the control logic 206 is configured to adjust the voltage across the gate of each transistor within each voltage regulator to either enable or disable the voltage regulator. The control logic 206 may enable or disable each voltage regulator using two switches – one between the amplifier and the gate of the PFET and one between the input voltage rail and the gate of the PFET. When a voltage regulator is enabled, the voltage regulator will contribute a voltage to the voltage domain to maintain the expected output voltage. When a voltage regulator is disabled, the voltage regulator will not contribute a voltage to the voltage domain.

The control logic 206 may be within the voltage domain 202 on the integrated circuit 200. Alternatively, a portion or all of the control logic 206 may exist outside of the voltage domain 202 but within the integrated circuit 200 or outside the integrated circuit 200. Further, the control logic 206 may receive operational instructions from a voltage regulator test module on a computer system, such as the voltage regulator test module on the computer system of FIG. 1. The control logic may be preprogrammed with a testing order for the voltage regulators in the particular voltage domain. The one voltage regulator may be tested by initiating or continuing through the testing order programmed into the control logic.

The voltage detector 212 is a collection of electronic components configured to measure the regulated output voltage 216 of the voltage regulators (voltage regulator A 204A, voltage regulator B 204B, voltage regulator C 204C, voltage regulator D 204D, voltage regulator E 204E, voltage regulator F 204F). The voltage detector 212 may be configured to measure the regulated output voltage 216 with only one voltage regulator enabled while the other voltage regulators in the voltage domain 202 are disabled (e.g., via the control logic 206). The voltage comparator 214 is a collection of electronic components configured to compare the output voltage obtained by the voltage detector 212 to a preset expected voltage and provide an indication regarding the comparison. The indication may be sent to a target external to the integrated circuit, such as the voltage regulator test module of FIG. 1. Although depicted within the voltage domain 202 in FIG. 2, the voltage detector 212 and/or voltage comparator 214 may be external to the voltage domain 202 while still residing on the integrated circuit 200.

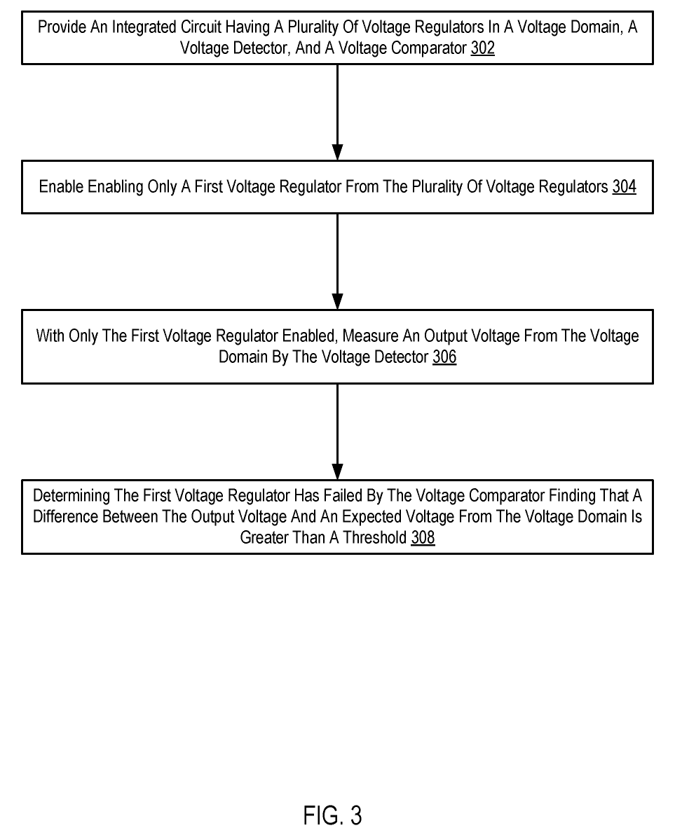

FIG. 3 sets forth a flowchart of an example method for detecting distributed voltage regulator failures according to aspects of the present disclosure. The method of FIG. 3 describes testing a first voltage regulator within a voltage domain and detecting a failure. The method of FIG. 3 may be performed before and/or after other voltage regulators within the voltage domain are tested and no failure is detected.

The method of FIG. 3 includes providing 302 an integrated circuit having a plurality of voltage regulators in a voltage domain, a voltage detector, and a voltage comparator. Providing 302 such an integrated circuit may be carried out by the integrated circuit described in FIG. 2.

The method of FIG. 3 also includes enabling 304 only a first voltage regulator from the plurality of voltage regulators. In one or more embodiments, enabling 304 only a first voltage regulator from the plurality of voltage regulators is carried out by introducing a voltage to one or more pins of the integrated circuit. The voltage applied may be a voltage for which the integrated circuit has been designed. The particular voltage domain under test may be powered independently from the other voltage domains of the integrated circuit.

Enabling 304 only a first voltage regulator from the plurality of voltage regulators may also be carried out by disabling each of the plurality of voltage regulators within the voltage domain of the integrated circuit except for the first voltage regulator. In one or more embodiments, disabling each of a plurality of voltage regulators within a voltage domain of an integrated circuit is carried out by sending a control signal to each of the voltage regulators via control logic coupled to the voltage regulators. The signal may adjust the voltage across the gate of a transistor within each voltage regulator to disable the voltage regulator. Specifically, the control logic uses the switches within the circuitry to disable the voltage regulator by opening the switch between the amplifier and the PFET and closing the switch from the input voltage rail.

Enabling 304 only a first voltage regulator from the plurality of voltage regulators may also be carried out by sending a control signal to the first voltage regulator via control logic coupled to the voltage regulators. The signal may adjust the voltage across the gate of a transistor within the first voltage regulator to enable the voltage regulator. Specifically, the control logic uses the switches within the circuitry to enable the first voltage regulator by closing the switch between the amplifier and the PFET and opening the switch from the input voltage rail. The voltage regulators in the voltage domain may be enabled by default when a voltage is applied to the integrated circuit or voltage domain. Alternatively, each voltage regulator in the voltage domain is enabled after the voltage is applied to the voltage domain.

Enabling 304 only a first voltage regulator from the plurality of voltage regulators may also be carried out by first enabling each voltage regulator in the plurality of voltage regulators followed by disabling each of the plurality of voltage regulators except for the first voltage regulator. Alternatively, enabling 304 only a first voltage regulator from the plurality of voltage regulators may also be carried out by first disabling each voltage regulator in the plurality of voltage regulators followed by enabling only the first voltage regulator.

Additionally, other loads within the voltage domain may be disabled or otherwise taken offline during the testing of the output voltage. Because operational loads, such as other electronic components, may alter the output voltage, those loads may be disabled so as not to cause the output voltage to signal failure where no failure exists.

The first voltage regulator may be the only voltage regulator in the voltage domain undergoing the test. Specifically, the other voltage regulators may comprise each of the voltage regulators in the voltage domain excluding the first voltage regulator. Alternatively, one or more other voltage regulators in the voltage domain may remain enabled as the output voltage of the voltage domain is compared to the expected voltage. For example, in order to efficiently discover a failure among a group of voltage regulators in a voltage domain, groups of two or more voltage regulators may remain enabled as the output voltage of the voltage domain is compared to the expected voltage. If a failure is detected within a group, then a smaller group or individual voltage regulators within that group may be tested.

The method of FIG. 3 also includes, with only the first voltage regulator enabled, measuring 308 an output voltage from the voltage domain by the voltage detector. In one or more embodiments, the first voltage regulator is enabled (or left enabled) during the measurement of the output voltage on the voltage domain. In one or more embodiments, measuring 308 an output voltage from the voltage domain by the voltage detector is carried out by measuring the output voltage at a connection to the drains of the voltage regulators. The output voltage may be measured at a point closer to the drain of the first voltage regulator (the voltage regulator under test) than to the drains of the other voltage regulators. The input voltage refers to the voltage supplied to the voltage domain. The output voltage refers to the voltage provided by one or more of the voltage regulators. The expected voltage refers to the voltage level at which the voltage regulators within the voltage domain were designed to provide. The expected voltage may be equal to an input voltage for the plurality of voltage regulators. Alternatively, the expected voltage may be some percentage of the input voltage. The output voltage may be the regulated output voltage as described above.

The method of FIG. 3 also includes determining 310 the first voltage regulator has failed by the voltage comparator finding that a difference between the output voltage and an expected voltage from the voltage domain is greater than a threshold. In one or more embodiments, determining 310 the first voltage regulator has failed by the voltage comparator finding that a difference between the output voltage and an expected voltage from the voltage domain is greater than a threshold is carried out by measuring the difference between the output voltage and the expected voltage from the measurement and determining whether that difference is greater than the threshold. The threshold is an amount of acceptable voltage tolerance between the output voltage of the voltage regulator and the expected voltage. The threshold may be based on measurements from other integrated circuits tested previously. Detecting that a difference between the output voltage and the expected voltage is greater than the threshold indicates that the voltage regulator under test has failed and is not operating as designed.

Once the voltage comparator and/or voltage regulator test module determines that the difference between the output voltage and the expected voltage is greater than the threshold, then integrated circuit may be marked as defective. Alternatively, the control logic may be used to disable the failed voltage regulator (and any loads dependent upon the voltage regulator being operational) permanently.

Once the first voltage regulator is tested, additional tests may be performed on other voltage regulators in the voltage domain until each voltage regulator in the voltage domain has been tested. For example, the method may further include enabling only a second voltage regulator from the plurality of voltage regulators; with only a second voltage regulator enabled, measuring an output voltage from the voltage domain by the voltage detector; and determining the second voltage regulator has not failed by the voltage comparator finding that a difference between the output voltage and the expected voltage from the voltage domain is not greater than a threshold.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
providing an integrated circuit having a plurality of voltage regulators in a voltage domain, a voltage detector, and a voltage comparator;
enabling only a first voltage regulator from the plurality of voltage regulators;
with only the first voltage regulator enabled, measuring an output voltage from the voltage domain by the voltage detector; and
determining the first voltage regulator has failed by the voltage comparator finding that a difference between the output voltage and an expected voltage from the voltage domain is greater than a threshold.

2. The method of claim 1, further comprising:
disabling the first voltage regulator;
enabling only a second voltage regulator from the plurality of voltage regulators;
with only the second voltage regulator enabled, measuring the output voltage from the voltage domain by the voltage detector; and
determining the second voltage regulator has not failed by the voltage comparator finding that a difference between the output voltage and the expected voltage from the voltage domain is not greater than the threshold.

3. The method of claim 1, wherein enabling only the first voltage regulator from the plurality of voltage regulators comprises sending a control signal to each of the plurality of voltage regulators via a control logic unit coupled to the voltage regulators.

4. The method of claim 1, wherein enabling only the first voltage regulator from the plurality of voltage regulators comprises applying a voltage to the first voltage regulator.

5. The method of claim 1, wherein the threshold is an amount of acceptable voltage variation tolerance between output voltage of the plurality of voltage regulators and the expected voltage.

6. The method of claim 1, wherein the plurality of voltage regulators is distributed across the voltage domain.

7. The method of claim 1, wherein each voltage regulator in the plurality of voltage regulators is a low-dropout regulator.

8. The method of claim 1, wherein the expected voltage is equal to an input voltage for the plurality of voltage regulators.

9. The method of claim 1, wherein each voltage regulator in the plurality of voltage regulators comprises an amplifier and a transistor.

10. The method of claim 1, wherein the voltage domain is a first voltage domain and the integrated circuit further comprises a second voltage domain.

11. A computer system comprising:
a processor set;
one or more computer-readable storage media; and
program instructions stored on the one or more computer-readable storage media to cause the processor set to perform operations comprising:
providing an integrated circuit having a plurality of voltage regulators in a voltage domain, a voltage detector, and a voltage comparator;
enabling only a first voltage regulator from the plurality of voltage regulators;
with only the first voltage regulator enabled, measuring an output voltage from the voltage domain by the voltage detector; and
determining the first voltage regulator has failed by the voltage comparator finding that a difference between the output voltage and an expected voltage from the voltage domain is greater than a threshold.

12. The computer system of claim 11, wherein the operations further comprise:
disabling the first voltage regulator;
enabling only a second voltage regulator from the plurality of voltage regulators;
with only the second voltage regulator enabled, measuring the output voltage from the voltage domain by the voltage detector; and
determining the second voltage regulator has not failed by the voltage comparator finding that a difference between the output voltage and the expected voltage from the voltage domain is not greater than the threshold.

13. The computer system of claim 11, wherein enabling only the first voltage regulator from the plurality of voltage regulators comprises sending a control signal to each of the plurality of voltage regulators via a control logic unit coupled to the voltage regulators.

14. The computer system of claim 11, wherein enabling only the first voltage regulator from the plurality of voltage regulators comprises applying a voltage to the first voltage regulator.

15. The computer system of claim 11, wherein the threshold is an amount of acceptable voltage variation tolerance between output voltage of the plurality of voltage regulators and the expected voltage.

16. The computer system of claim 11, wherein the plurality of voltage regulators is distributed across the voltage domain.

17. The computer system of claim 11, wherein each voltage regulator in the plurality of voltage regulators is a low-dropout regulator.

18. The computer system of claim 11, wherein the expected voltage is equal to an input voltage for the plurality of voltage regulators.

19. The computer system of claim 11, wherein each voltage regulator in the plurality of voltage regulators comprises an amplifier and a transistor.

20. A computer program product comprising:
one or more computer-readable storage media; and
program instructions stored on the one or more storage media to perform operations comprising:
providing an integrated circuit having a plurality of voltage regulators in a voltage domain, a voltage detector, and a voltage comparator;
enabling only a first voltage regulator from the plurality of voltage regulators;
with only the first voltage regulator enabled, measuring an output voltage from the voltage domain by the voltage detector; and
determining the first voltage regulator has failed by the voltage comparator finding that a difference between the output voltage and an expected voltage from the voltage domain is greater than a threshold.
